(19) United States
(12) Patent Application Publication
(10) Pub. No.: US 2011/0019128 A1
(43) Pub. Date: Jan. 27, 2011

(54) OPTICAL MEMBER, LIGHTING DEVICE, DISPLAY DEVICE, TELEVISION RECEIVER AND MANUFACTURING METHOD OF OPTICAL MEMBER

(75) Inventor: Yoshiki Takata, Osaka-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/922,179

(22) PCT Filed: Nov. 17, 2008
(86) PCT No.: PCT/JP2008/070844

§ 371 Date: Sep. 13, 2010

(30) Foreign Application Priority Data
Mar. 27, 2008 (JP) 2008-083927

(51) Int. Cl. G02F 1/13357; G02B 27/12; F21V 5/04; G03F 7/20

(52) U.S. Cl. 349/62; 359/619; 359/628; 362/311.1; 430/321

(57) ABSTRACT

An optical member 15 includes a planar light transmissive sheet 22 and a number of convex microlenses 23 provided in random settings within a surface of the light transmissive sheet 22. By providing a number of the convex microlenses 23 within the surface of the light transmissive sheet 22, moire patterns are less likely to be created even when the optical member 15 is overlaid on a liquid crystal panel 11 having pixels PE that are regularly arranged.

### TECHNICAL FIELD

The present invention relates to an optical member, a lighting device, a display device, a television receiver and a manufacturing method of the optical member.

### BACKGROUND ART

A liquid crystal panel generally included in a liquid crystal display device and a backlight device, which is an external lighting device, arranged behind a liquid crystal display panel. The backlight device includes a plurality of cold cathode tubes, which are linear light sources and an optical member for converting light emitted from each cold cathode tube into planar light. The optical member includes multiple layers, such as a diffuser plate, a diffuser sheet, a lens sheet and a brightness enhancement sheet. The optical member having such a structure tends to diffuse the emitted light in a direction toward where no display device is present and thus light use efficiency is low. An example of an optical member in which light use efficiency is improved is disclosed in Patent Document 1.

Patent Document 1: Japanese Published Patent Application No. 2005-221619

### PROBLEM TO BE SOLVED BY THE INVENTION

The optical member disclosed in Patent Document 1 includes a lens section in which a plurality of unit lenses are disposed on a surface and a light reflecting layer having openings on the other surface. The light reflecting layer is provided in an area corresponding to a non-light collecting area of the unit lenses, and the openings are provided in areas corresponding to light collecting areas of the unit lenses. Therefore, a light diffusing angle is easily adjusted only by adjusting a ratio between an area of the light reflecting layer and that of the openings. Namely, the amount of light traveling in directions that are not related to display decreases and this improves the light use efficiency.

However, the following problem may occur when such an optical member is used. If interference occurs between a pattern of pixels in a liquid crystal panel and a pattern of the unit lenses in the lens section, moire patterns, which are interference patterns, may be created. Such moire patterns may reduce the sharpness of a display device and cause a poor display quality.

### DISCLOSURE OF THE PRESENT INVENTION

The present invention was made in view of the foregoing circumstances. An object of the present invention is to reduce the generation of moire patterns.

### Means for Solving the Problem

An optical member of the present invention includes a planar base and a number of convex microlenses provided in random settings within a surface of the base.

By providing a number of the convex microlenses in random settings within the surface of the base, moire patterns are less likely to be created when the optical member is used in a display device.

Furthermore, to solve the above problem, the optical member of the present invention is to be overlaid on a display panel in which a large number of pixels are regularly arranged. The optical member includes a planar base and a number of convex microlenses provided within a surface of the base. The microlenses are provided in at least two different sizes within the surface of the base. The sizes are smaller than a half size of each pixel.

Because the microlenses are provided in at least two different sizes within the surface of the base and the sizes are smaller than a half size of each pixel of a display panel, the moire patterns are less likely to be created in a display device in which the optical member is used.

Furthermore, to solve the above problem, a lighting device of the present invention includes the above-described optical member, a chassis in which the optical member is arranged on a light output side and a lamp housed in the chassis.

The moire patterns are less likely to be created in a display device in which the lighting device is used.

Furthermore, to solve the above problem, a display device of the present invention includes the above-described lighting device and a display panel arranged in front of the lighting device .

Because the moire patterns are less likely to be created in this display device, preferable display performance can be achieved.

Furthermore, to solve the above problem, an optical member manufacturing method of the present invention includes forming a number of microlenses convex toward a surface of a planar base and in random settings, forming a photosensitive adhesive layer via the microlenses, exposing the photosensitive adhesive layer via the microlenses, forming reflection type material layer on the exposed photosensitive adhesive layer. The exposing step creates unexposed areas with adhesiveness in the photosensitive adhesive layer around borders between the microlenses due to a light collecting ability of the microlenses and exposed areas without adhesiveness. The reflection type material layer forming step forms the reflection type material layers selectively on the unexposed areas of the photosensitive adhesive layer.

With this method, the reflection type material layers are properly formed in the areas corresponding to the border areas between the microlenses provided in random settings. Therefore, the high quality optical member that can control the generation of moire patterns can be produced.

### BRIEF DESCRIPTION OF THE DRAWINGS

FIG. 1 is an exploded perspective view illustrating a general construction of a liquid crystal display device according to the first embodiment of the present invention;

FIG. 2 is a cross-sectional view of a general construction of the liquid crystal display device;

FIG. 3 is a perspective view of a television receiver including the liquid crystal display device;

FIG. 4 is an explanatory view illustrating an arrangement of pixels in the liquid crystal display device;

FIG. 5 is a cross-sectional view of an optical member;

FIG. 6 is an explanatory view illustrating a general arrangement of microlenses of the optical member;

FIG. 7 is a normal distribution curve of planar area sizes of the microlenses;

FIG. 8 is a chart illustrating a relationship between moire levels and locations on a flat surface of an optical member according to the embodiment;

FIG. 9 is a chart illustrating a relationship between moire levels and locations on a flat surface of an optical member according to a comparative example;

FIG. 10 is a cross-sectional view illustrating an exposing step of exposing a negative-type photosensitive resin layer via a photo mask in a lens forming process;

FIG. 11 is a cross-sectional view illustrating a light transmissive sheet bonded to a rear surface of the hardened areas;

FIG. 12 is a cross-sectional view illustrating the optical member with unhardened area removed;

FIG. 13 is a cross-sectional view illustrating an exposing step for exposing a positive-type photosensitive resin layer via a photo mask in a lens forming process;

FIG. 14 is a cross-sectional view of lens sheets including light transmissive sheets in different thicknesses produced in a sheet thickness adjusting process;

FIG. 15 is a cross-sectional view illustrating a photosensitive material layer formed on a rear surface of the lens sheet;

FIG. 16 is a cross-sectional view illustrating the photosensitive layers exposed via the microlenses;

FIG. 17 is a curve illustrating a relationship between thickness of the light transmissive sheet and size of the exposed area;

FIG. 18 is a cross-sectional view illustrating a photosensitive adhesive layer formed on a rear surface of the light transmissive sheet in the reflection layer forming process;

FIG. 19 is a cross-sectional view illustrating the photosensitive adhesive layer exposed via the microlenses

FIG. 20 is a cross-sectional view illustrating light reflecting layers formed in the optical member;

FIG. 21 is a chart illustrating a relationship between locations on a flat surface of an optical member according to the second embodiment of the present invention and levels of a moire pattern;

FIG. 22 is a chart illustrating a relationship between locations on a surface of an optical member according to a comparative example and levels of a moire pattern;

FIG. 23 is a cross-sectional view illustrating an optical member according to other embodiment (2) of the present invention; and

FIG. 24 is a cross-sectional view illustrating an optical member according to other embodiment (3) of the present invention

### BEST MODE FOR CARRYING OUT THE INVENTION

### First Embodiment

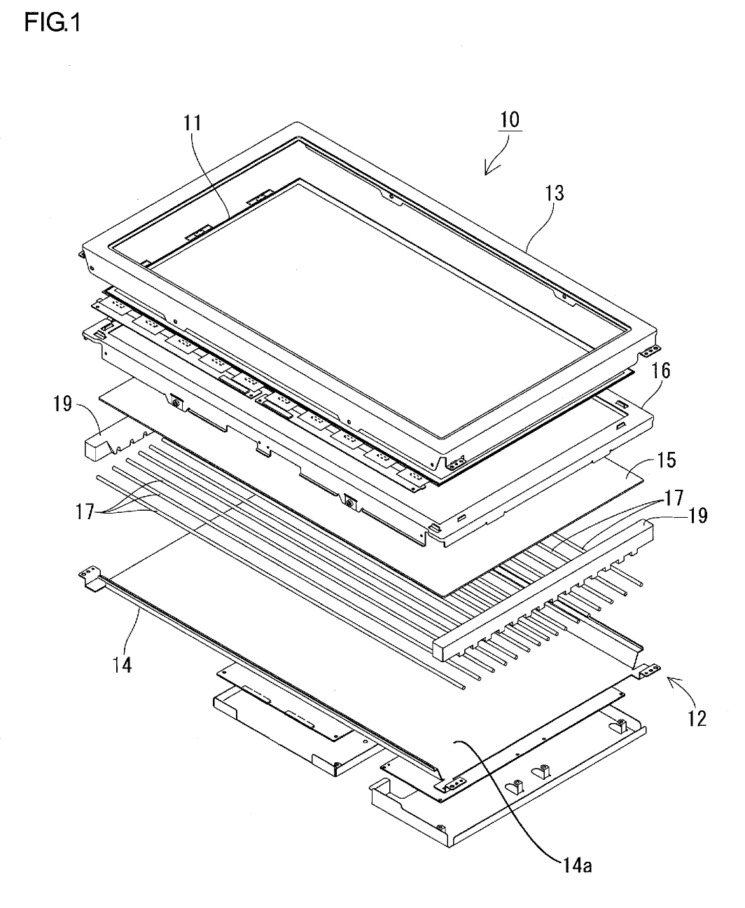

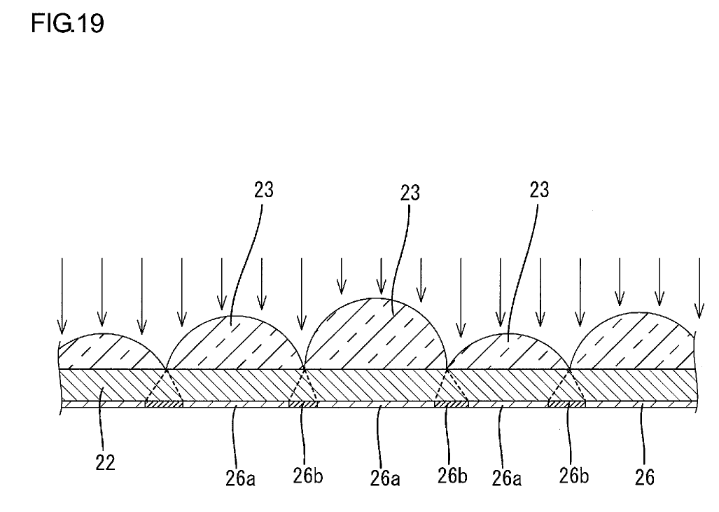

The first embodiment of the present invention will be explained with reference to FIGS. 1 to 20.

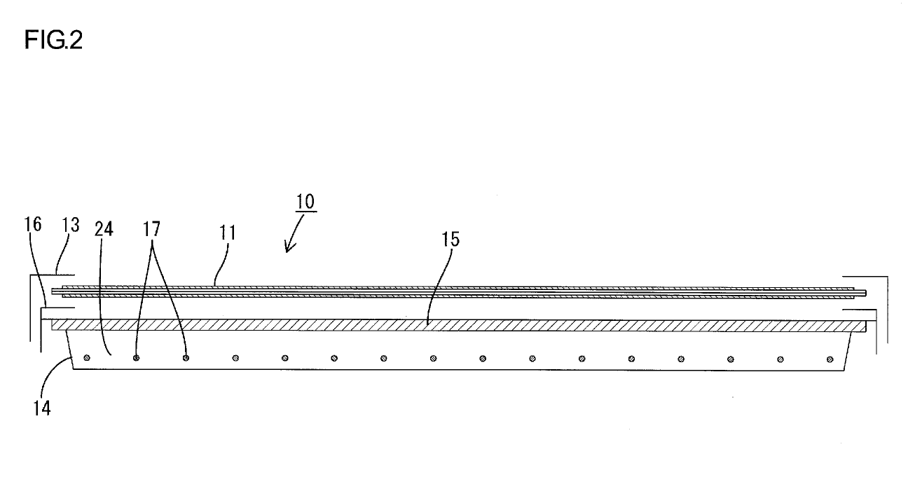

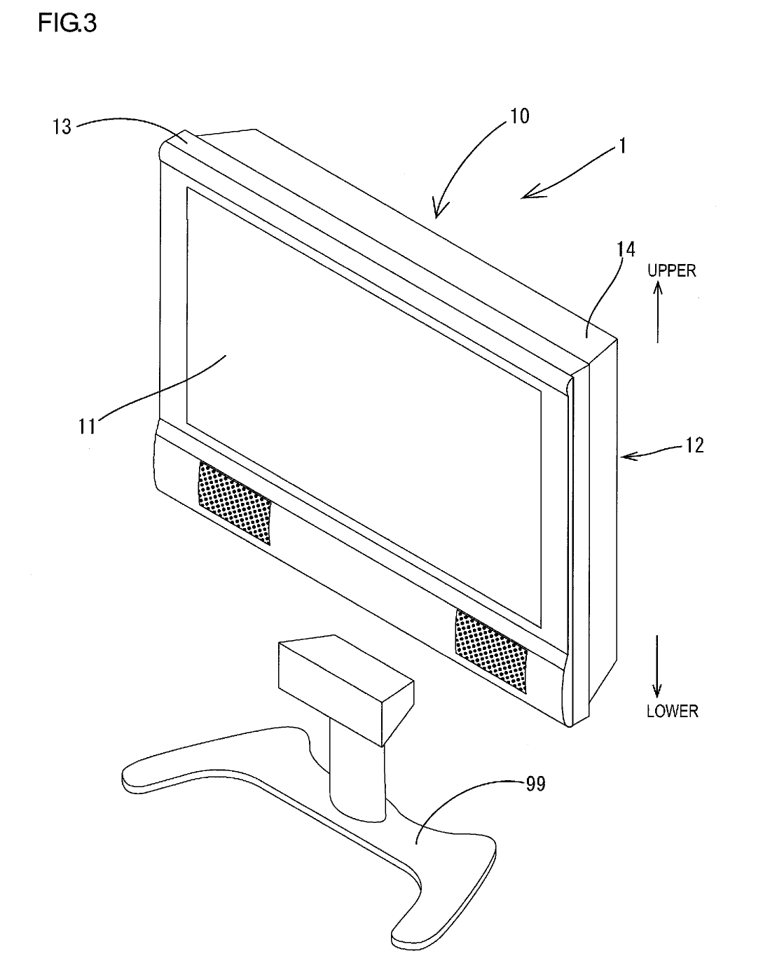

As illustrated in FIGS. 1 and 2, a liquid crystal display device 10 of this embodiment includes a liquid crystal panel (display panel) 11 and a backlight unit (lighting device) 12. The liquid crystal panel 11 has a rectangular shape in plan view. The backlight unit 12 is an external light source. They are held together with a bezel 13. As illustrated in FIG. 3, the liquid crystal display device 10 can be used for a television receiver 1. The television receiver 1 includes the liquid crystal display device 10 in which the liquid crystal panel 11 and the backlight unit 12 are held together with the bezel 13 and a stand 99 that supports the liquid crystal display device 10.

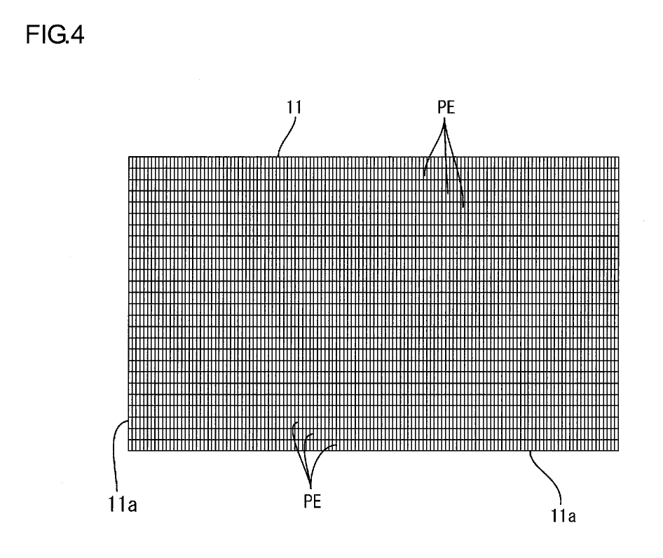

The liquid crystal panel 11 has a know configuration in which liquid crystals (liquid crystal layer) that change optical characteristics according to application of voltages are sealed between the transparent TFT substrate and CF substrate. On an inner surface of the TFT substrate, a number of source lines that extend in the length direction and a number of gate lines that extend in the width direction. They form a matrix . In each square defined by those lines, a number of pixels PE are arranged in matrix (see FIG. 4). Arrays of the pixels PE (pixel arrays) are parallel to a long-side edge or a short-side edge 11a, as illustrated in FIG. 4. Pitches of the lines or intervals between the arrays of the pixels PE may vary depending on a screen size or the number of pixels of the liquid crystal panel 11. For example, in the liquid crystal panel having 45-inch screen size and 1920×1080 pixels, the intervals of the arrays of the pixels PE (pixel pitches) are about 513 μm in ling side and 171 μm in short side (one third of the long side).

The CF substrate has color filters of red (R), green (G) and blue (B). Polarizing plates are attached to the surfaces of those substrates away from the liquid crystals.

The backlight unit 12 is a direct backlight arranged directly behind the liquid crystal panel 11. It includes a chassis 14, a reflecting sheet 14a, an optical member 15, a frame 16, a plurality of cold cathode tubes 17 and lamp holders 19. The chassis has an opening on a front side (light output side). The reflecting sheet 14a is placed inside the chassis 14. The optical member 15 is attached over the opening of the chassis 14. The frame 16 fixes the optical member 15. The cold cathode tubes 17 are housed in the chassis 14. The lamp holders 19 fix the cold cathode tubes 17 to defined positions with respect to the chassis 14.

The chassis 14 is made of metal. It has a substantially box shape with a rectangular shape in plan view and an opening on the front side (light output side). The reflecting sheet 14a is made of synthetic resin in white having high reflectivity. It placed in the chassis 14 so as to cover almost the entire inner surface of the chassis 14. Most of light emitted from the cold cathode tubes 17 is directed toward the opening of the chassis with this reflecting sheet 14a. Each cold cathode tube 17 is one kind of linear light sources (tubular light source) and arranged inside the chassis with the axis thereof aligned with the longitudinal direction of the chassis 14. The cold cathode tubes 17 are arranged substantially parallel to each other with predetermined gaps therebetween.

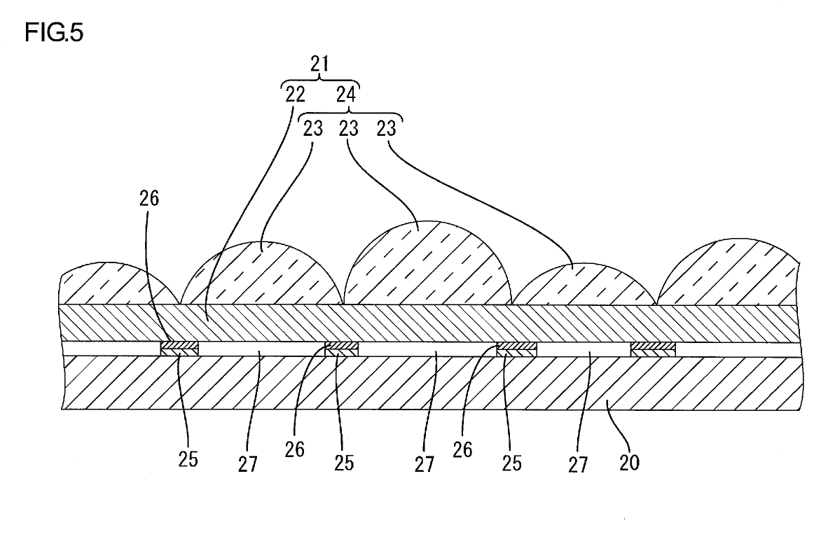

The optical member 15 converts linear light emitted from the cold cathode tubes 17, which are linear light sources, to planar light. It also directs the planar light toward an effective display area of the liquid crystal panel 11. The optical member 15 has a landscape rectangular shape similar to the liquid crystal panel 11 and the chassis 14 and a structure illustrated in FIG. 5. Specifically, a diffuser sheet 20 and a lens sheet 21 are bonded together. The diffuser sheet 20 includes a base made of light transmissive synthetic resin in which a large number of light scattering particles for scattering light are enclosed. The lens sheet 21 has a lens section (microlenses) 24 including a number of convex microlenses 23 disposed on a surface of a light transmissive sheet (light transmissive base) 22. Each microlens 23 is a convex lens having a substantially hemispheric shape with an ellipsoidal plan view and arranged with a long axis thereof aligned with the longitudinal direction of the optical member 15, that is, the horizontal direction of the liquid crystal display device 10 (the direction perpendicular to the vertical direction).

Light reflecting layers are formed between the diffuser sheet 20 and the lens sheet 21 selectively in areas overlapping border areas between the microlenses 23 in plan view. The light reflecting layers 25 are bonded to the rear surface of the light transmissive sheet 22 via adhesive layers 26. Light transmitting spaces 27 are provided between the light reflecting layers 25, that is, in areas that overlap areas in which focal points of the microlenses 23 are located in plan view. The light reflecting layers 25 are provided in areas, each of which has a predetermined width with a bottom of a valley between the adjacent microlenses 23 as a center. The light transmitting spaces 27 are provided in areas, each of which has a predetermined width with a top of the corresponding microlens 23. Namely, the light reflecting layers 25 correspond the non-light collecting areas of the microlenses 23 and the light transmitting spaces 27 correspond the light collecting areas of the microlenses 23. The light transmitting spaces 27 are air spaces and the reflective index thereof is different from that of the diffuser sheet 20 or the lens sheet 21. The light reflecting layers 25 are made of transparent resin in which white titanium oxide particles are dispersed, for example.

How light directed to the optical member 15 from the rear acts will be explained. The light emitted from the cold cathode tubes 17 passes through the light transmitting spaces 27 and enters the microlenses 23. It is output with its travel direction adjusted toward an effective display area of the liquid crystal panel 11. Light that does not pass through the light transmitting spaces 27 is reflected by the light reflecting layers 25 and returns to the cold cathode tubes 17. It is repeatedly reflected by the reflecting sheet 14a until it finally passes through the light transmitting spaces 27. Namely, the optical member 15 is configured to reuse the light. The optical member is also configured to properly adjust the travel direction of the light (diffusing angle) by adjusting the ratio between the width of the light reflecting layers and that of the light transmitting spaces 27. Each microlens 23 has an ellipsoidal shape in plan view elongated in the horizontal direction as described above. Therefore, the light can be directed more widely in the horizontal direction than in the vertical direction and thus the liquid crystal display device 10 has a wide viewing angle in the horizontal direction.

When designing the microlenses 23 of the optical member 15, the planar area (the top-view sizes on the surface of the optical member 15) of each microlens 23 may not be set larger than the planar area of the pixels PE, otherwise the microlenses 23 may be recognized. If the planar area of the microlenses 23 is set to about the same as that of the pixels PE and the microlenses 23 are regularly arranged (e.g., in a grid pattern similar to the pixels PE), moire patterns are more likely to be created. “The planar area of the microlenses” is a size that measures in the long-axis direction or in the short-axis direction.

After a process of trial and error with such problems in consideration, the inventor of this application has found out that moire patterns are less likely to be created even when the microlenses 23 are regularly arranged if the planar area sizes of the microlenses 23 are set to very small sizes, for instance, one third of the planar area sizes of the pixels PE. However, processing the microlenses 23 in such small sizes is difficult due to a processing accuracy.

With further trial and error, the inventor has found out that moire patterns are less likely to be created without processing the microlenses 23 into very small sizes when the microlenses 23 are prepared in different settings. Next, preparation of the microlenses 23 with different settings will be explained in detail.

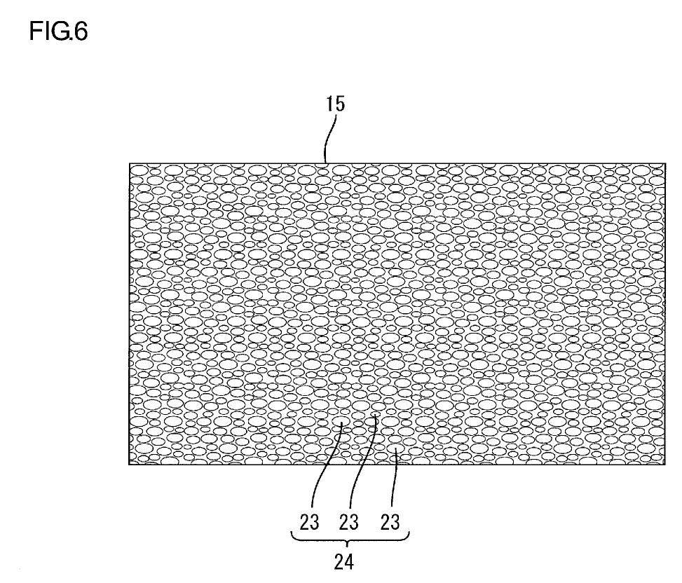

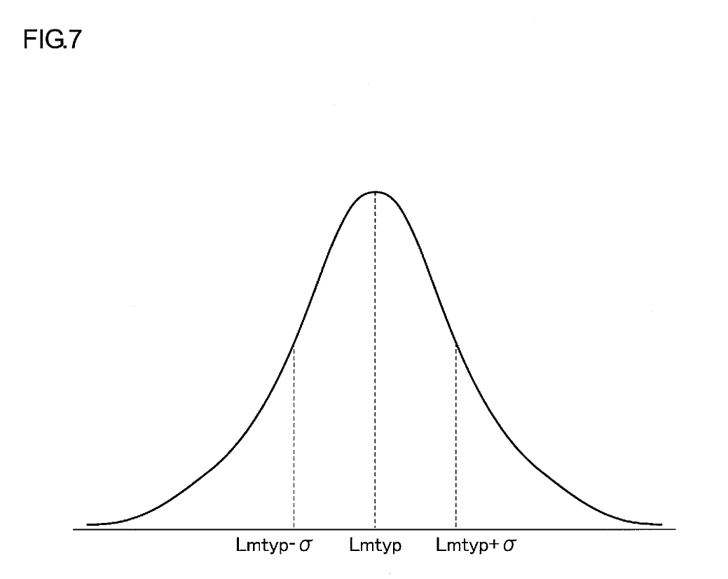

“Preparation of the microlenses 23 indifferent settings” includes different conceptual approaches. The first approach is preparing the microlenses 23 in different planar area sizes (top-view sizes on the surface of the light transmissive sheet 22). “Preparing the microlenses 23 in different planar area sizes” means that at least one of the long-axis sizes and the short-axis sizes of the microlenses 23 are defined with different settings. FIG. 6 illustrates the microlenses 23, both long-axis sizes and short-axis sizes of which are defined with different settings. However, the microlenses 23 can be prepared only with the long-axis sizes or the short-axis sizes defined in different settings. The microlenses 23 are prepared in the different planar area sizes such that the planar area sizes Lm form a normal distribution with a mean Lmtyp and a standard deviation σ as illustrated in FIG. 7. Moire patterns are less likely to be created when the planar area sizes Lm of the microlenses 23 moderately vary within the normal distribution so as not to have structural regularity in plan view. The random settings described above does not exclude sizes of the microlenses 23 in the lens section 24 larger than that of the pixels PE. A small number of the microlenses 23 larger than the pixels PE can be included. In this case, the number of the microlenses 23 having sizes larger than the pixels PE should be controlled such that such microlenses 23 are present in an area three times larger than the standard deviation σ. This reduces visual strangeness.

Setting of the standard deviation σ that expresses the degree of the variations (degree of scatter) will be explained in detail. If the planar area of the pixel PE in the liquid crystal panel 11 is Lp, the ratio n between the planar area Lm of the microlenses 23 and the planar area Lp is expressed by expression 1 provided below.

n=Lp/Lm (1)

If n>2 in expression 1, the standard deviation σ should be set within a range expressed by expression 2 provided below. If n is larger than 2, the planar area Lm of the microlenses 23 is smaller than a half of the planar area Lp of the pixels PE.

(Lmtyp−σ)≦Lp/(n×1.1)≦Lm≦Lp/n≦(Lmtyp+σ) (2)

Expression 2 expresses that the standard deviation σ sets a range of the planar area sizes Lm of the microlenses 23 between Lp/(n×1.1) and Lp/n or wider.

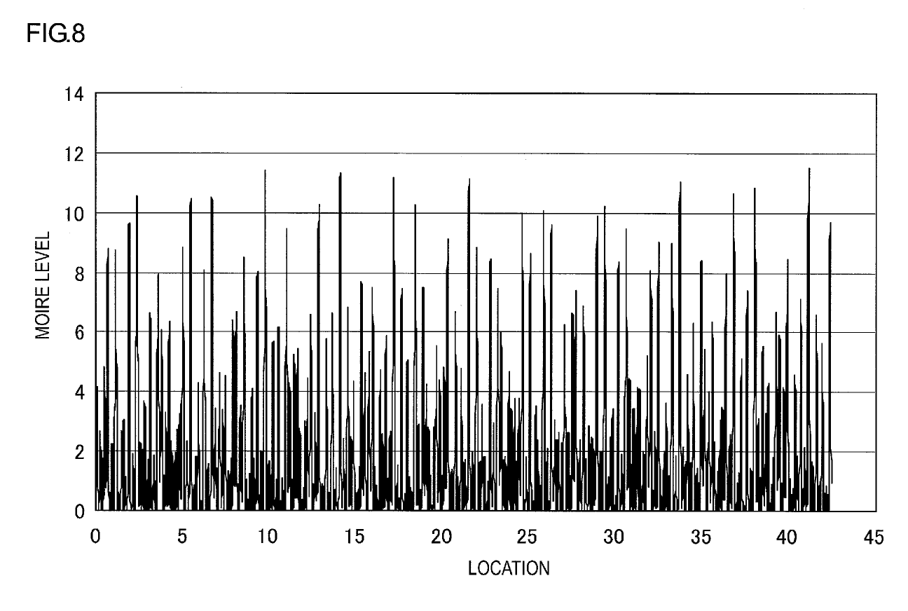

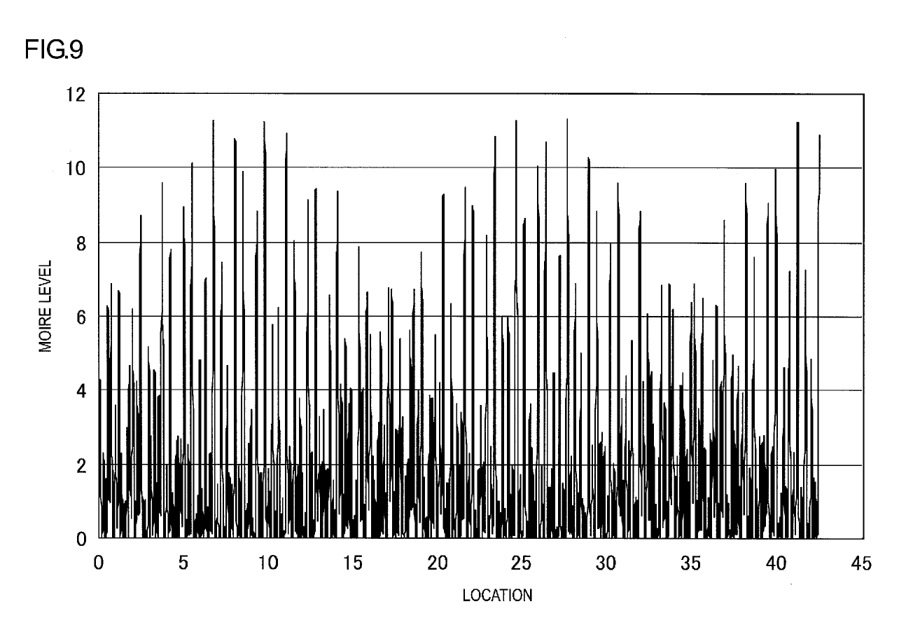

A specific example with n set to 2.1 is provided below. FIG. 8 illustrates the microlenses 23 provided with the planar area sizes Lm thereof in different seizes that form the normal distribution expressed by (Lmtyp−σ)=Lp/2.31≦Lm≦Lp/2.1=(Lmtyp+σ). FIG. 9 illustrates a comparative example of the microlenses 23 provided with the planar area sizes Lm thereof in different seizes that fall in the normal distribution expressed by (Lmtyp−σ)=Lp/2.2≦Lm≦Lp/2.1=(Lmtyp+σ). The vertical axes in FIGS. 8 and 9 indicate the moire levels and the horizontal axes indicate locations on the surface of the light transmissive sheet 22. The comparative example includes the microlenses 23 with the lower degree of variations in the planar area Lm, that is, a larger number of the microlenses 23 in similar sizes are included.

Recognizable peaks are not present in the moire level chart of the example illustrated in FIG. 8. The moire levels are generally averaged out. Therefore, the moire patterns are less likely to be seen. In the comparative example in FIG. 9, recognizable peaks are present in the moire level chart and thus the moire patterns are more likely to be seen in comparison to the example. These results show that the moire levels tend to be more averaged out by increasing the degree of the variations in the planar area sizes Lm of the microlenses 23, that is, the degree of scatter of the microlenses 23. Therefore, the moire patterns are less likely to be created by setting the standard deviation σ in the range between Lp/(n×1.1) and Lp/n or wider. This improves the display quality of the liquid crystal display device.

A relationship expressed by expression 3 provided below can be derived from expression 2.

(Lmtyp−σ)/(Lmtyp+σ)≦n/(n×1.1) (3)

Next, the second approach of “preparation of the microlenses 23 in different settings” will be explained. The second approach is randomly arranging the microlenses 23 within the surface of the light transmissive sheet 22. As illustrated in FIGS. 5 and 6, the microlenses 23 are randomly arranged on the surface of the light transmissive sheet 22. Namely, the microlenses 23 are arranged in an irregular layout on the surface of the light transmissive sheet 22 so as not to have structural regularity in plan view. More specifically, lines that connect the centers of he microlenses 23 having ellipsoidal shapes in plan view do not form a regular pattern such as a grid pattern or a plurality of patterns do not appear in a specific layout (or specific sequence). An unspecific number of patterns appear in unspecific sequence. By randomly arranging the microlenses 23, interference patterns are less likely to be created between the microlenses 23 and the pixels PE regularly arranged in the liquid crystal panel 11. As a result, the moire patterns are further less likely to be recognized with this approach together with the first approach.

The third approach of “preparation of the microlenses 23 in different settings” will be explained. The third approach is preparing the microlenses 23 in different heights from the surface of the light transmissive sheet 22. As illustrated in FIG. 5, the heights of the microlenses 23 from the surface of the light transmissive sheet 22 are irregular, that is, the microlenses 23 have no structural regularity in the normal-line direction with respect to the surface and thus have no optical regularity. Therefore, interference patterns are less likely to be created between the microlenses 23 and the pixels PE regularly arranged in the liquid crystal panel 11. As a result, the moire patterns are further less likely to be recognized with this approach together with the first and the second approaches. “Preparing the microlenses 23 in different heights” does not exclude providing some of the microlenses 23 in the same height. The differences in heights of the microlenses 23 having hemispheric shapes should be within a range of the variations in Lm/2. The range is wider than a range of production error that occurs during production of the microlenses in the same height.

Although the microlenses 23 are prepared in different heights as described above, the curvatures of the surfaces (lens surfaces) thereof are substantially the same. The microlenses 23 having substantially the same curvatures show the same light collecting ability. With this configuration, uneven brightness is less likely to occur when the optical member 15 is viewed at an angle, that is, from the directions that cross the surface of the optical member 15 and the normal direction thereof while the optical member 15 is illuminated from the rear.

By providing the microlenses 23 in the different planar area sizes, arrangement and heights, the generation of the moire patterns is properly controlled while the planar area sizes of the microlenses 23 are still large enough for easy processing. Preferable planar area sizes of the microlenses 23 are 10 μm or larger. It is especially preferable if the microlenses have 50 μm or larger in long-axis sizes that are more easily produced.

The thickness of the light transmissive sheet 22 on which the microlenses 23 are provided in random settings as described above has correlation with an average focal point (focal distance) of the microlenses 23. Because the planar area sizes and the heights of the microlenses 23 are in random settings, the focal points are also located at random. The thickness of the light transmissive sheet 22 is defined such that the rear surface, that is, the opposite surface from the lens section 24 is located at the same plane on which the average focal point of the microlenses 23 is on or inside the plane (closer to the microlenses 23). Namely, the average focal point of the microlenses 23 is on the rear surface of the light transmissive sheet 22 or outside the light transmissive sheet 22. With this configuration, the light collecting ability of the microlenses 23 can be improved.

Next, a manufacturing method of manufacturing the optical member 25 having the above configurations. In brief, the optical member 15 is produced by preparing the lens sheet 21, the light transmissive sheet 22 and the diffuser sheet 20 separately and bonding them together.

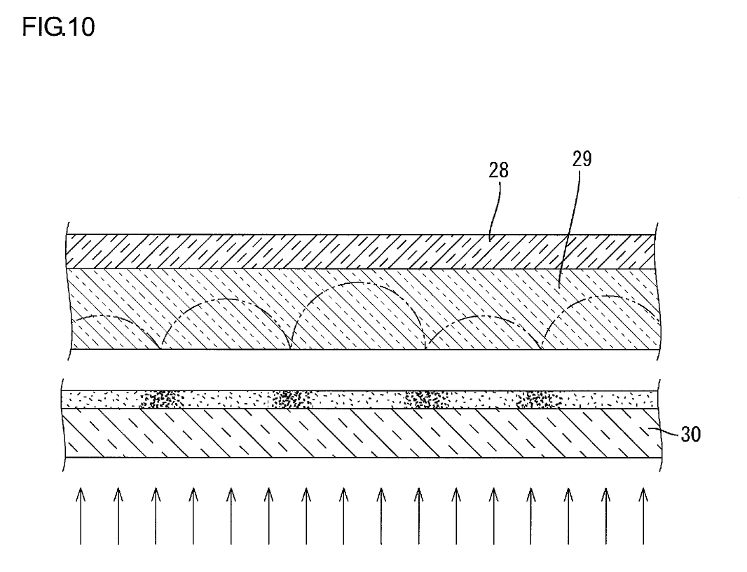

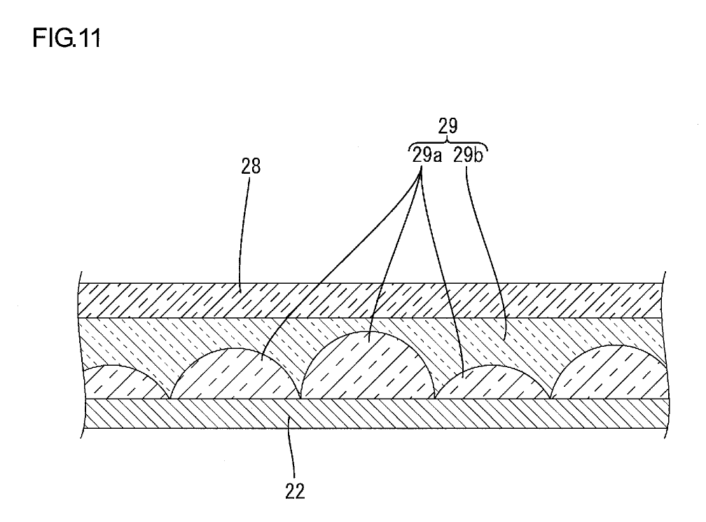

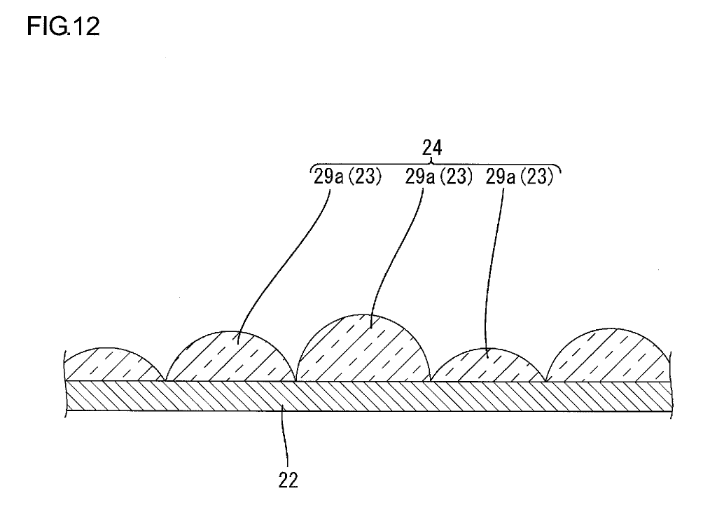

First, a lens forming process for forming the microlenses 23 on the lens sheet 21 in random settings will be explained in detail. As illustrated in FIG. 10, a negative-type photosensitive resin layer 29 is formed on a rear surface of a transparent fixing board 28 and a photo mask 30 is placed on the rear of the photosensitive resin layer 29. The photo mask 30 prepared in gray scales has random patterns corresponding the microlenses 23 in random settings. The photosensitive resin layer 29 is exposed from the rear via the photo mask 30 (exposing process). As illustrated in FIG. 11, the exposed areas of the photosensitive resin layer 29 are hardened and hardened areas 29a are formed. The unhardened area 29b is formed in the unexposed area. After the light transmissive sheet 22 is bonded to the rear of the photosensitive resin layer 29, the fixing board 28 is removed. When the photosensitive resin layer 29 is developed, the unhardened area is removed but the hardened areas 29a remain on the light transmissive sheet 22 as illustrated in FIG. 12 (developing process). The hardened areas 29 are the microlenses 23 provided in random settings.

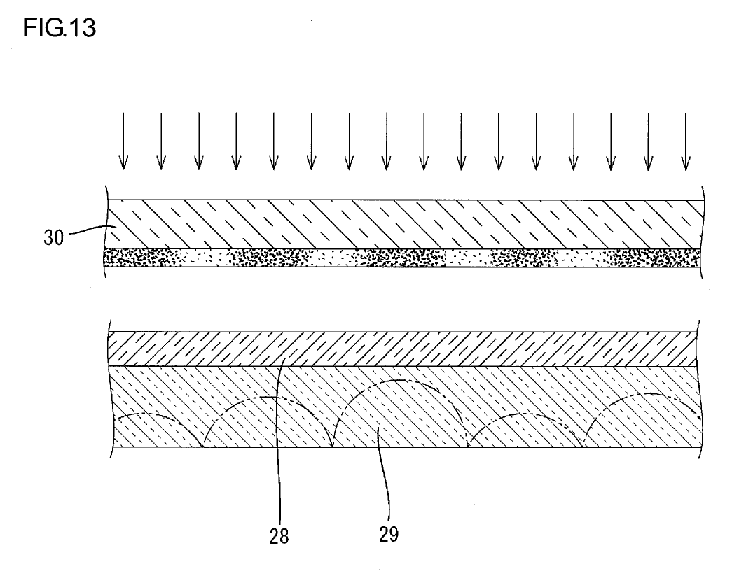

The photosensitive resin layer 29 can be a positive type. In this case, a photo mask 30 having positive-type random patterns is placed on the positive-type photosensitive resin layer 29 formed on the rear surface of the fixing board 28 as illustrated in FIG. 13. When the photosensitive resin layer 29 is exposed via the photo mask 30, the exposed area becomes an unhardened area 29b and the unexposed areas become hardened areas 29a (see FIG. 11). Then, the light transmissive sheet 22 is bonded to the rear of the photosensitive resin layer 29. When the fixing board 28 is removed and the photosensitive resin layer 29 is exposed, the unhardened area 29b is removed and the hardened areas 29a remain on the light transmissive sheet 22. As a result, the microlenses 23 are formed of the hardened areas 29a in random settings (see FIG. 12).

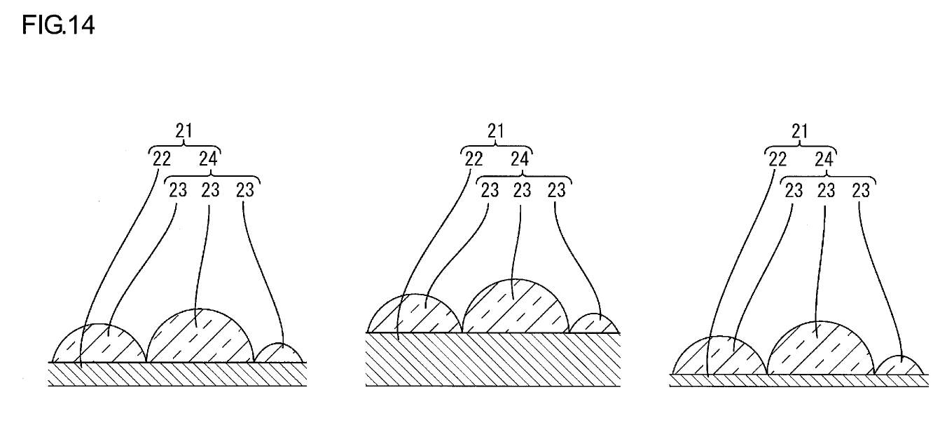

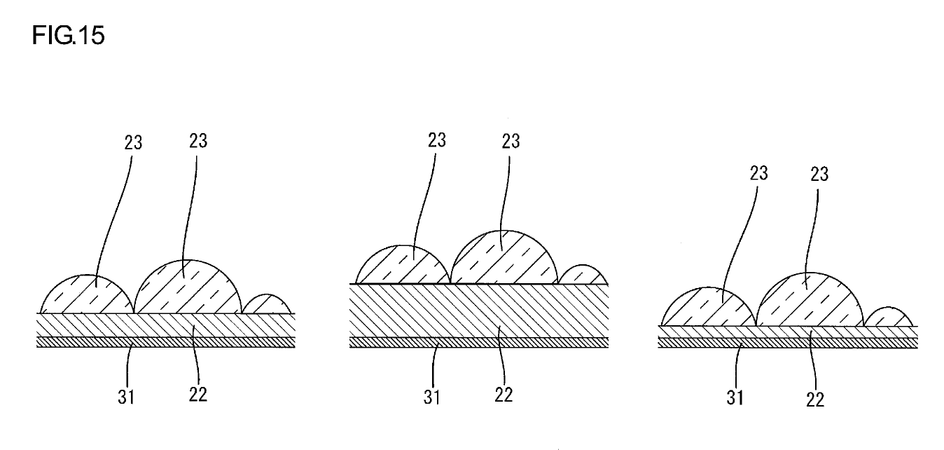

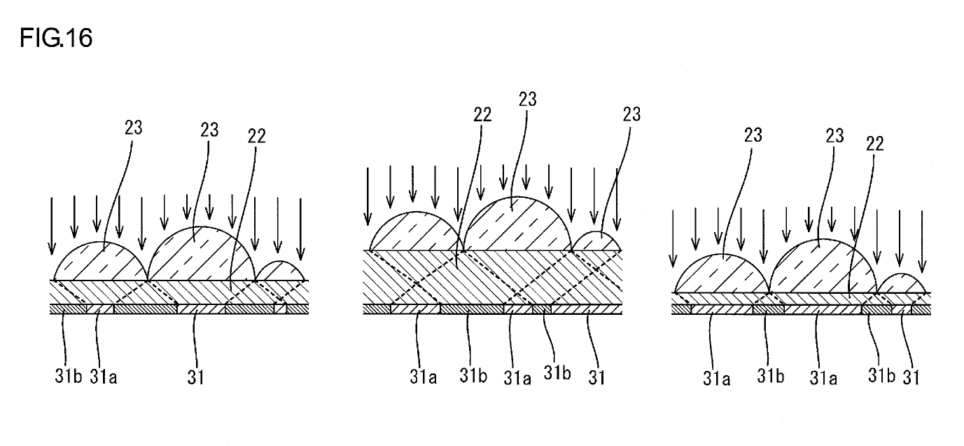

Next, a sheet thickness adjusting process for adjusting the thickness of the light transmissive sheet 22 will be explained. The sheet thickness adjusting process is performed prior to mass production of the optical member 15. This process determines the most appropriate thickness of the light transmissive sheet 22 for the microlenses 23 in random settings. First, a number of the light transmissive sheets 22 in different thicknesses are prepared to produce a number of the lens sheets 21 in different thicknesses as illustrated in FIG. 14 in the lens forming process described above. Only three lens sheets 21 are illustrated in FIGS. 14 to 16, respectively, due to limitation of space. As illustrated in FIG. 15, the photosensitive material layer 31 is formed on a rear surface of each light transmissive sheet 22. The photosensitive material used here can be either negative type or positive type. Each lens sheet 21 is exposed to parallel light on the front for exposing the photosensitive material layer 31. The photosensitive material layer 31 is exposed via the microlenses 23 as illustrated in FIG. 16 (exposing process). Because of the light collecting ability of the microlenses 23, areas of the photosensitive material layer 31 corresponding to light condensing areas of the microlenses 23 are exposed and become exposed areas 31a. Areas corresponding to non-light condensing areas of the microlenses 23 become unexposed areas 31b.

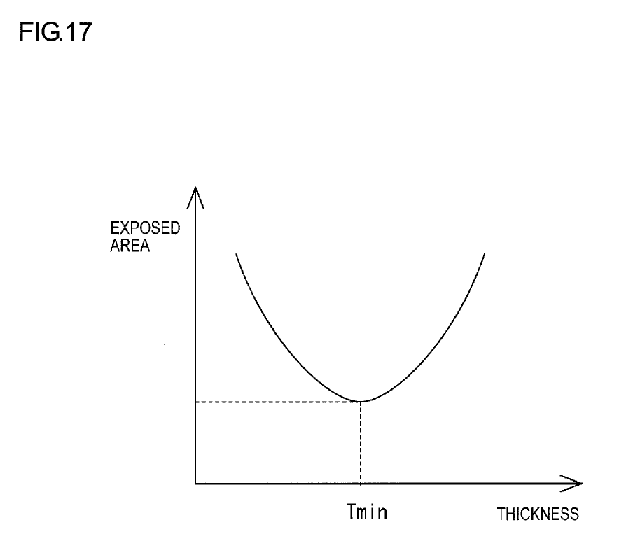

Then, the photosensitive material layer 31 is developed and the unexposed areas 31b are removed (developing process). An unexposed area of the photosensitive material layer 31 is calculated (sheet thickness calculating process). The unexposed area differs depending on the thickness of the light transmissive sheet 22. The relationship between them is illustrated in FIG. 17. From the curve illustrated in FIG. 17, the thickness Tmin of the light transmissive sheet 22 in the minimum exposed area is obtained. When the thickness is Tmin, a plane on which the average focal point of the microlenses 23 is located substantially matches the rear surface of the light transmissive sheet 22. If the thickness of the light transmissive sheet 22 is smaller than Tmin, the plane on which the average focal point of the microlenses 23 is located is outside the light transmissive sheet 22. If the thickness of the light transmissive sheet 22 is larger than Tmin, the plane on which the average focal point of the microlenses 23 is located is inside the light transmissive sheet 22. In the mass production of the optical members 15, the average focal point of the microlenses in random settings can be set on a plane that substantially matches the rear surface of the light transmissive sheet 22 or outside by setting the thickness of the light transmissive sheet 22 to Tmin or smaller. Therefore, the light collecting ability of the microlenses 23 can be improved.

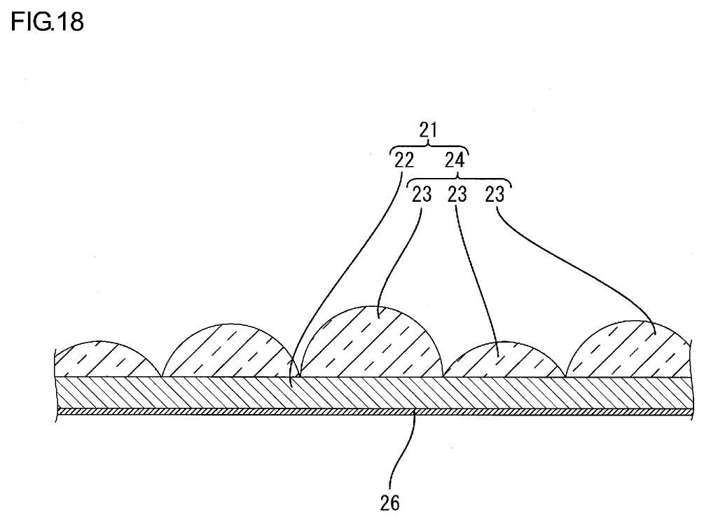

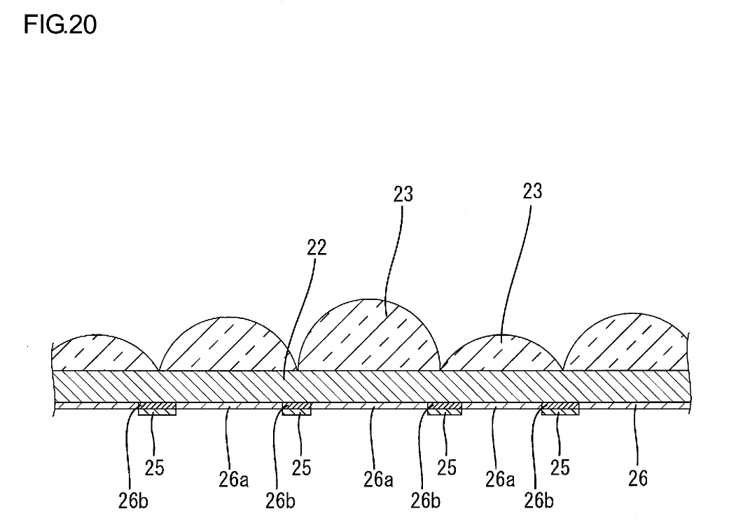

Next, a process of forming the light reflecting layers selectively in the areas corresponding to the border areas between the microlenses in random settings on the rear surface of the light transmissive sheet 22 bonded to the lens sheet 21. As illustrated in FIG. 18, the photosensitive adhesive layer 26 is formed on the rear surface of the light transmissive sheet 22. The lens sheet 21 is exposed to parallel light from the front to expose the photosensitive adhesive layer 26 via the microlenses 23 (exposing process). Because of the light collecting ability of the microlenses 23, areas of the photosensitive adhesive layer 26 corresponding to light condensing areas of the microlenses 23 are exposed and areas corresponding to non-light condensing areas of the microlenses 23 are unexposed. The exposed areas 26a of the photosensitive adhesive layer 26 lose adhesive properties but the unexposed areas 26b maintain the adhesive properties. As illustrated in FIG. 20, the light reflecting layers 25 are formed on the rear surface of the photosensitive adhesive layer 26. The light reflecting layers 25 are formed selectively in areas that overlap the unexposed areas 26b of the photosensitive adhesive layer 26, the unexposed areas 26b having the adhesive properties. They are not formed in areas that overlap the exposed areas 16b having no adhesive properties. Namely, the light reflecting layers 25 are formed selectively in the areas corresponding to the border areas between the microlenses 23.

After the light reflecting layers 25 are formed as described above, the diffuser sheet 20 is bonded to the light transmissive sheet 22 from the rear with the light reflecting layers 25 therebetween. The optical member 15 having the structure illustrated in FIG. 5 is produced.

The optical member produced as described above is installed in the backlight unit 12 of the liquid crystal display device 10. When the liquid crystal display device displays images, the cold cathode tubes 17 in the backlight unit 12 are lit and image signals are sent to the liquid crystal panel 11. Linear light emitted from the cold cathode tubes 17 is converted to planar light in the process of passing the light through the optical member and directed toward the liquid crystal panel 11 with angles suitable for display. Therefore, high quality images can be displayed.

Specifically, the light emitted from the cold cathode tubes 17 is diffused with the diffusing particles in the diffuser sheet 20 of the optical member 15 when passing through the diffuser sheet 20. After passing through the light transmitting spaces 27 corresponding to the light collecting areas of the microlenses 23, the light enters the microlenses 23. It is directed toward the effective display area of the liquid crystal panel 11. The light that does not pass through the light transmitting spaces 27 is reflected by the light reflecting layers 25 and turns toward the cold cathode tubes 17. It is reflected by the reflecting sheet 14a toward the microlenses 23 again. Therefore, the light emitted from the cold cathode tubes 17 is effectively used and thus high brightness can be achieved. Because each microlens 23 has an ellipsoidal shape elongated in the horizontal direction of the liquid crystal display device 10 in which it is installed, the light can be output with a wide angle in the horizontal direction. Therefore, the liquid crystal display device 10 has a wide viewing angle in the horizontal direction.

The optical member 15 includes the microlenses 23 that are formed with structural irregularity in plan view and in optically random settings. Therefore, interference patterns are less likely to be created between the optical member 15 and the liquid crystal panel 11 in which the pixels PE are regularly arranged in plan view. As a result, moire patterns are less likely to be created on a displayed image and thus high quality display can be provided.

The optical member 15 of this embodiment includes the planar light transmissive sheet 22 and a large number of the convex microlenses 23 formed within the surface of the light transmissive sheet 22 in random settings, as described above. Because a large number of the convex microlenses 23 are formed within the surface of the light transmissive sheet 22, moire patterns are less likely to be created even when the optical member 15 is overlaid on the liquid crystal panel 11 in which the pixels PE are regularly arranged.

The light reflecting layers 25 are electively formed in the areas corresponding to the border areas between the microlenses 23 on the opposite surface of the light transmissive sheet 22 from the surface on which the microlenses 23 are formed. With this configuration, the light diffusing angles are easily adjusted by adjusting the sizes of the light reflecting layers 25. This reduces the light that travels in the unwanted directions and thus the light use efficiency improves.

The planar diffuser sheet 20 is arranged such that the light reflecting layers 25 are sandwiched between the light transmissive sheet 22 and the diffuser sheet 20. With this configuration, the light is diffused by the diffuser sheet 20 before entering the microlenses 23. Therefore, uneven brightness is preferably reduced.

The microlenses 23 have planar areas within the light transmissive sheet 22 in different sizes. By providing the microlenses 23 in different planar area sizes, the generation of moire patterns is properly controlled.

When a planar area of each microlens 23 within the surface of the light transmissive sheet 22 is Lm, the planar areas in different sizes Lm that form a normal distribution with a mean Lmtyp and a standard deviation σ. By setting the sizes of the microlenses so as to form a normal distribution, the generation of moire patterns is properly controlled.

The optical member 15 is overlaid on the liquid crystal panel 11 in which a number of the pixels PE are regularly arranged. If the planar area of the pixel PE is Lp and the ratio n between Lm and Lp is expressed by n=Lp/Lm (n>2), Lm is defined to satisfy the expression (Lmtyp−σ)≦Lp/(n×1.1)≦Lm≦Lp/n≦(Lmtyp+σ). By setting the standard deviation σ of the microlenses 23 in the range between Lp/(n×1.1) and Lp/n or wider, the generation of moire patterns is properly controlled.

The microlenses 23 are randomly arranged within the surface of the light transmissive sheet 22. By randomly arranging the microlenses 23, the generation of moire patterns is properly controlled.

The microlenses 23 are provided in different heights from the surface of the light transmissive sheet 22. By providing the microlenses 23 in different heights, the generation of moire patterns is properly controlled.

The curvatures of the microlenses 23 are set substantially the same. By setting the curvatures substantially the same for the microlenses 23 having different heights, uneven brightness due to the viewing angles can be reduced.

The light transmissive sheet 22 has a rectangular shape and each microlens 23 has an ellipsoidal shape. The microlenses 23 are provided with the long-axes thereof aligned with the longitudinal direction of the light transmissive sheet 22. With this configuration, the light can be output with wide angles in the longitudinal direction of the light transmissive sheet 22.

The optical member 15 is configured such that the average focal point of the microlenses 23 are on the plane that substantially matches the opposite surface of the light transmissive sheet 22 from the microlenses 23 or outside the surface. With this configuration, the light collecting ability of the microlenses 23 is improved.

The manufacturing method of manufacturing the optical member 15 according to this embodiment includes the lens forming process, the photosensitive adhesive forming process, the exposing process and the light reflecting layer forming process. The lens forming process forms a number of the convex microlenses 23 in random settings on a surface of the planar light transmissive sheet 22. The photosensitive adhesive forming process forms the photosensitive adhesive layers 26 on the opposite surface of the light transmissive sheet 22 from the microlenses 23. The exposing process exposes the photosensitive adhesive layers 26 via the microlenses 23. The light reflecting layer forming process forms the light reflecting layers 25 (light reflecting material) on the exposed photosensitive adhesive layers 26. The exposing process forms the unexposed areas 26b in the areas of the photosensitive adhesive layers 26 corresponding to the border areas between the microlenses 23 due to the light collecting ability of the microlenses 23. The unexposed area 26b have adhesive properties and the exposed areas 26a have no adhesive properties. The light reflecting layer forming process forms the light reflecting layers 25 selectively on the unexposed areas 26b of the photosensitive adhesive layers 26. With this method, the light reflecting layers 25 are properly formed in the areas corresponding to the border areas between the microlenses 23 provided in random settings. As a result, the high quality optical member 15 is produced.

The lens forming process includes the photosensitive resin layer forming process, the exposing process and the developing process. The photosensitive resin layer forming process forms the photosensitive resin layer 29. The exposing process exposes the photosensitive resin layer 29 via the photo mask 30 having patterns corresponding to sizes, shapes and locations of the microlenses 23. The exposing process then forms the hardened areas 29a and the unhardened area 29b in the photosensitive resin layer 29. The developing process develops the photosensitive resin layer 29 and removes the unhardened area 29b. The developing process forms the microlenses 23 with the remaining hardened areas 29a. With this method, the microlenses 23 are properly formed in random settings and thus the high quality optical member is produced.

The method includes the sheet thickness adjusting process of adjusting the thickness of the light transmissive sheet 22. The sheet thickness adjusting process includes the microlens forming process, the photosensitive material layer forming process, the exposing process, the developing process and the calculating process. The microlens forming process forms the microlenses 23 on the light transmissive sheets 22 having different thicknesses. The photosensitive material layer forming process forms the photosensitive material layer 31 on the opposite surface of the light transmissive sheet 22 from the microlenses 23. The exposing process exposes the photosensitive material layer 31 via the microlenses 23 and forms the hardened areas 31a and the unhardened areas 31b in the photosensitive material layer 31. The developing process develops the photosensitive material layer 31 and removes the unhardened areas 31b. The sheet thickness calculating process calculates the thickness of the light transmissive sheet 22 in the smallest exposed area. With this method, the thickness of the light transmissive sheet 22 can be set equal to the thickness in the smallest exposed area calculated in the sheet thickness calculating process or smaller. By setting the thickness as such, the average focal point of the microlenses 23 is set on a plane that substantially matches the opposite surface of the light transmissive sheet 22 from the microlenses 23 or outside the surface. This improves the light collecting ability of the microlenses 23.

### Second Embodiment

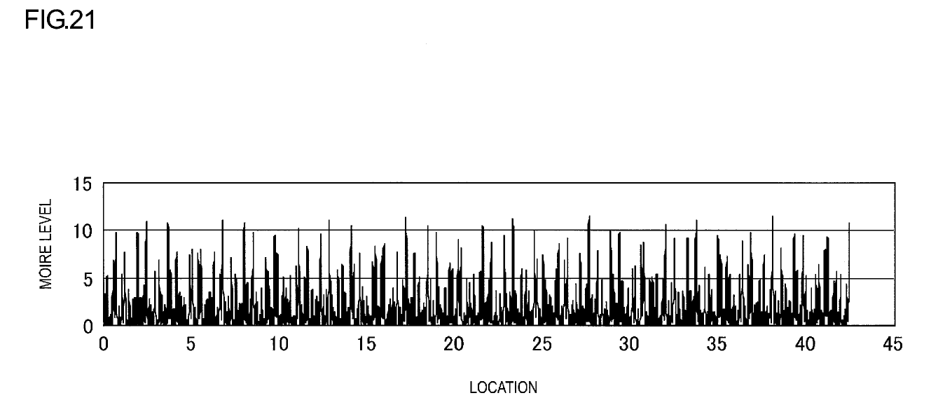

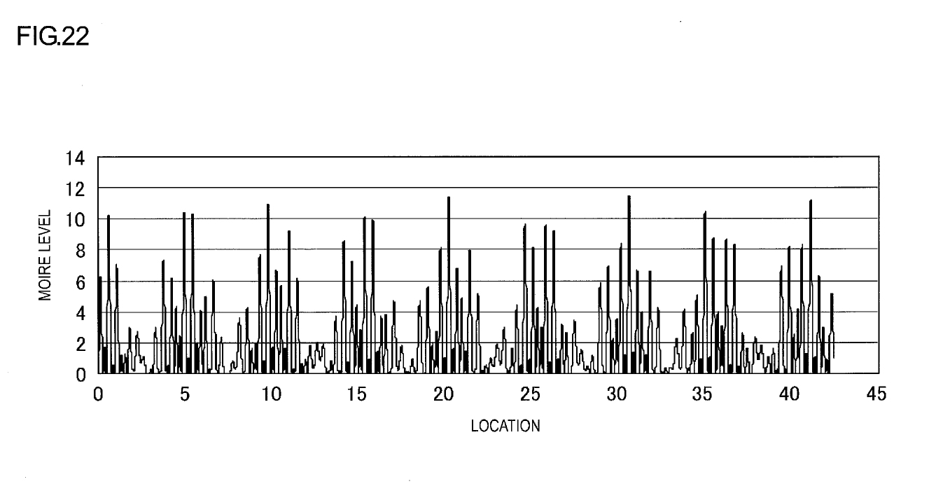

The second embodiment of the present invention will be explained with reference to FIGS. 21 and 22. In this embodiment, the microlenses 23 are provided in two sizes. Structures, functions and effects same as the first embodiment will not be explained.

The microlenses 23 formed on the optical member according to this embodiment are in two different planar area sizes. The microlenses 23 include large microlenses 23A and small microlenses 23B. This embodiment restricts generation of moire patterns by setting the planar area sizes of the large microlenses 23A and the small microlenses 23B such that differences between them and the planar area sizes of the pixels PE in the liquid crystal panel 11 are larger than a specific value.

Settings of the planar area sizes of the small and the large microlenses 23 will explained in detail. When the planar area size of the large microlenses 23A is Lm1 and that of the small microlenses 23B is Lm2, a ratio n1 between the planar area size Lm1 of the large microlenses 23A and the planar area size Lp of the pixels PE, and a ratio n2 between the planar area size Lm2 of the small microlenses 23B and Lp are expressed by expression 4 provided below.

n1=Lp/Lm1

n2=Lp/Lm2

n1<n2 (4)

When n1 and n2 in expression 4 are n1>2 and n2>2,that is, the planar area sizes of the large microlenses 23A and the small microlenses 23B are set smaller than a half of the planar area size of the pixels PE in the liquid crystal panel 11, the preferable moire pattern reduction effect can be achieved. FIG. 21 illustrates a measurement result of the embodiment with n1=2.1 and n2=3.1. FIG. 22 illustrates a comparative example with n1=1.1 and n2=2.1. In the actual measurement, a difference between the planar area sizes of the large microlenses 23A and the small microlenses 23B is set about 15% of the planar size Lp of the pixels PE. FIG. 21 does not show Recognizable peaks are not present in the moire level chart in FIG. 21 and the moire levels are generally averaged out. Namely, the generation of moire patterns is preferably restricted. Recognizable peaks are present in the moire level chart in FIG. 22 and thus the moire patterns are more likely to be recognized in comparison to the embodiment.

From these results, when the microlenses 23 are provided in two different planar area sizes that are smaller than a half of the planar area size of the pixels PE, the generation of moire patterns is more properly restricted than the microlenses provided in sizes equal to a half of the planar area size of the pixels PE or larger such as the comparative example. This improves the display quality of the liquid crystal display device 10.

Even when the microlenses 23 are regularly arranged, this embodiment can provide moire pattern restricting effects higher than the comparative example having the same arrangement. Further, even when the microlenses 23 are provided in the same height, this embodiment can provide moire pattern restricting effects higher than the comparative example having the same heights. Still further, even when the microlenses 23 are provided with the same curvature, this embodiment can provide moire pattern restricting effects higher than the comparative example having the same curvature.

As described above, the optical member 15 of this embodiment is overlaid on the liquid crystal panel 11 in which a number of the pixels PE are regularly arranged. It includes the planar light transmissive sheet 22 and a number of the convex microlenses 23 formed within the surface of the light transmissive sheet 22. The microlenses 23 are provided in two different planar area sizes within the surface of the light transmissive sheet 22. The sizes are smaller than a half of the size of the pixels PE. Because the microlenses 23 are provided in two different planar sizes smaller than a half of the size of the pixels PE of the liquid crystal panel 11 within the surface of the light transmissive sheet 22, the generation of moire patterns is restricted even when the optical member 15 is overlaid on the liquid crystal panel 11 having the pixels PE that are regularly arranged.

### Other Embodiment

The present invention is not limited to the embodiments explained above with reference to the figures. For example, the following embodiments may be included in the technical scope of the present invention, for example.

(1) In the first embodiment, all of the three approaches are used to provide the microlenses in random settings. However, at least one of the approaches may be used. The optical members having such configurations can still provide the moire pattern restricting effects and are included in this invention. Examples (2) to (4) of the optical members having such configurations are provided below.

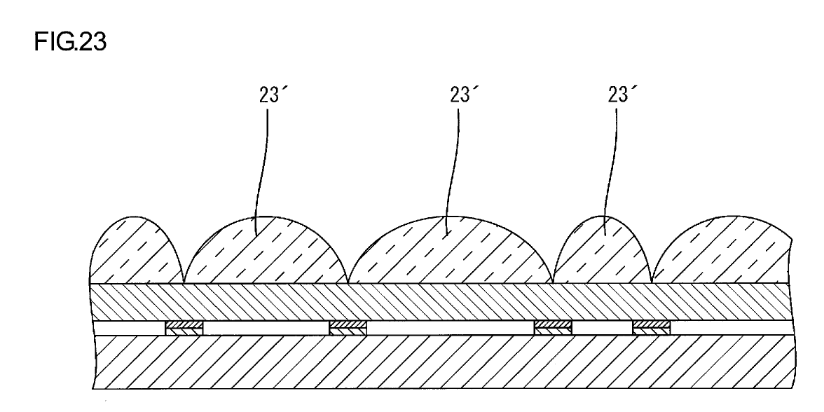

(2) As microlenses 23′ illustrated in FIG. 23, the planar area sizes may be set to different sizes while the heights are set constant and the arrangement thereof is in a regular layout. The microlenses 23′ may be provided in the same height in different planar area sizes and an irregular layout. The microlenses 23′ may be provided in different planar area sizes and in different heights in a regular layout.

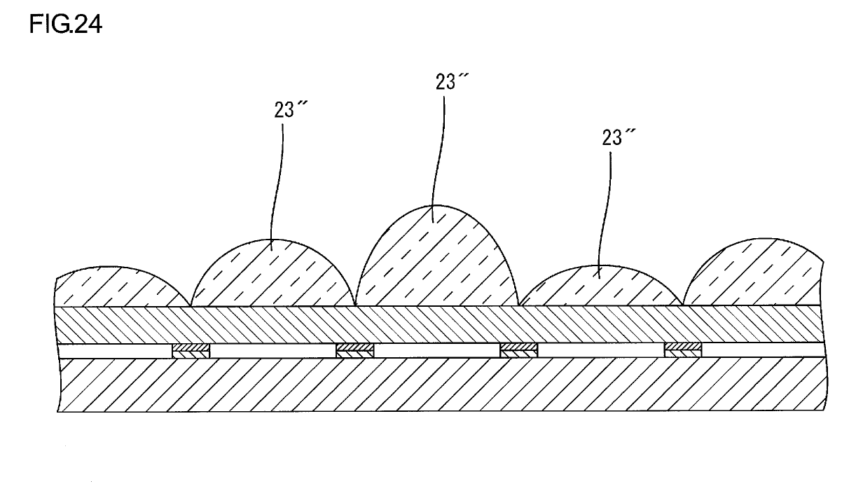

(3) As microlenses 23″ illustrated in FIG. 24, the heights may be set to different sizes while the planar area sizes are set constant and regularly arranged. The microlenses 23″ having the same planar area sizes may be provided in different heights and in an irregular layout.

(4) The microlenses having the same planar area size and the same height may be provided in a regular layout.

(5) In the first embodiment, the microlenses having different planar area sizes in the range defined by expression 2 with n=2.1 are used as an example. However, n can take any number larger than 2 (n>2). In this condition, the optical member can still provide proper moire pattern restricting effects.

(6) In the second embodiment, the microlenses having two different planar area sizes in the range defined by expression 4 with n1=2.1 and n2=3.1 are used as an example. However, n1 and n2 are not limited to 2.1 and 3.1, respectively. They can take any numbers larger than 2 (n1>2, n2>2). In this condition, the optical member can still provide proper moire pattern restricting effects.

(7) In the first embodiment, the microlenses having the same curvature are used as an example. However, microlenses having different curvatures may be included in the present invention. In this case, the microlenses do not need to have curvatures all different from each other, that is, some microlenses may have the same curvature.

(8) In the second embodiment, the microlenses are provided in two different planar area sizes. However, the microlenses in different planar area sizes more than two may be included in the present invention.

The above embodiments, the optical members including diffuser sheets bonded to the rear surfaces of the lens sheets. However, the optical members without the diffuser sheets may be included in the present invention. Moreover, the optical members without the light reflecting layers may be included in the present invention.

(10) In the above embodiments, the cold cathode tubes are used as light sources. However, other kinds of light sources including hot cathode tube scan be used.

(11) In the above embodiments, the TFTs are used as switching components of the liquid crystal display device. However, the optical member can be used in liquid crystal display devices using other switching components (e.g., thin film diodes (TFDs)) or in black-and-white liquid crystal display devices other than the color liquid crystal display devices.

(12) In the above embodiments, the liquid crystal display panels are used as display panels. However, the present invention can be applied to the display devices using other kinds of display panels.

(13) In the above embodiments, the television receiver including a tuner is used. However, the present invention can be applied to a display device without a tuner.

1. An optical member comprising:
a planar base; and
a plurality of convex microlenses provided in random settings.

2. The optical member according to claim 1, wherein light reflecting layers are formed on a surface of the base selectively in areas corresponding to border areas between the microlenses, the surface away from the microlenses.

3. The optical member according to claim 2, wherein a planar diffuser is arranged such that the light the light reflecting layers are sandwiched between the planar diffuser and the base.

4. The optical member according to claim 1, wherein the microlenses are provided in random sizes within the surface of the base.

5. The optical member according to claim 4, wherein the microlenses are provided within the surface of the base in sizes Lm that form a normal distribution with a mean Lmtyp and a standard deviation σ.

6. The optical member according to claim 5, wherein:
the optical member is to be overlaid on a display panel in which a large number of pixels are regularly arranged; and
the sizes Lm are defined so as to satisfy a relational expression of (Lmtyp−σ)≦Lp/(n×1.1)≦Lm≦Lp/n≦(Lmtyp+σ), where Lp is a size of each pixel and n is a ratio between the size Lp and corresponding one of the sizes Lm expressed by an expression n=Lp/Lm (n>2).

7. The optical member according to claim 1, wherein the microlenses are provided in a random arrangement within the surface of the base.

8. The optical member according to claim 1, wherein the microlenses are provided in different heights from the surface of the base.

9. The optical member according to claim 8, wherein the microlenses have a substantially same curvature.

10. The optical member according to claim 1, wherein:
the base has a rectangular shape; and
each of the microlenses is formed in an ellipsoidal shape a long axis of which is aligned along a long side of the base.

11. The optical member according to claim 1, wherein the microlenses are formed such that an average focal point thereof is set on a plane that substantially matches the surface of the base away from the microlenses or outside the surface.

12. An optical member to be overlaid on a display panel in which a number of pixels are regularly arranged, comprising:
a planar base; and
a number of convex microlenses provided within a surface of the base, wherein the microlenses are provided in at least two different sizes that are smaller than a half size of each of the pixels.

13. A lighting device comprising:
the optical member according to claim 1;
a chassis in which the optical member is arranged on a light output side; and
a lamp housed in the chassis.

14. A display device comprising:
the lighting device according to claim 13; and
a display panel arranged in front of the lighting device.

15. The display device according to claim 14, wherein the display panel is a liquid crystal panel including liquid crystals sealed between a pair of substrates.

16. A television receiver comprising the display device according to claim 14.

17. An optical member manufacturing method comprising:
forming a number of microlenses convex toward a surface of a planar base and in random settings;
forming photosensitive adhesive layers on a surface of the base away from the microlenses;
exposing the photosensitive adhesive layer via the microlenses; and
forming reflection type material layer on the exposed photosensitive adhesive layer, wherein:
the exposing step creates unexposed areas with adhesiveness in the photosensitive adhesive layer around borders between the microlenses due to a light collecting ability of the microlenses and exposed areas without adhesiveness; and
the reflection type material layer forming step forms the reflection type material layer selectively on the unexposed areas of the photosensitive adhesive layer.

18. The optical member manufacturing method according to claim 17, wherein the lens forming step includes:
forming a photosensitive resin layer;
exposing the photosensitive resin layer via a photo mask having a pattern corresponding to sizes, shapes and locations of the microlenses so as to form hardened areas and unhardened area in the photosensitive resin layer; and
forming the microlenses with the hardening areas by developing the photosensitive resin layer and removing the non-hardening areas.

19. The optical member manufacturing method according to claim 17, further comprising adjusting a thickness of the base, wherein the base thickness adjusting step includes:
forming the microlenses on a plurality of bases having different thicknesses;
forming photosensitive material layers on surfaces of the bases away from the microlenses;
forming hardened areas and unhardened area in the photosensitive material layers by exposing the photosensitive material layers via the microlenses;
developing the photosensitive material layers and removing the unhardened area; and
calculating the thicknesses of the bases in a smallest exposed area based on the thicknesses of the base and exposed areas of the photosensitive layers.
